(19) United States
(12) Patent Application Publication
(10) Pub. No.: US 2026/0255749 A1
(43) Pub. Date: Aug. 27, 2026

(54) CHIP PACKAGE STRUCTURE

(71) Applicant: EXCELLENCE OPTOELECTRONICS INC., Chunan Town (TW)

(72) Inventors: Kuo-Hsin HUANG, Chunan Town (TW); Chung-Yu CHOU, Chunan Town (TW); Wen-Hsing HUANG, Chunan Town (TW); Tzeng-Guang TSAI, Chunan Town (TW); Fu-Bang CHEN, Chunan Town (TW); Wei-Po SHEN, Chunan Town (TW); You-Chen WU, Chunan Town (TW)

(73) Assignee: EXCELLENCE OPTOELECTRONICS INC., Chunan Town (TW)

(21) Appl. No.: 19/251,542

(22) Filed: Jun. 26, 2025

(30) Foreign Application Priority Data
Feb. 25, 2025 (TW) 114201885

(51) Int. Cl. H10H 29/24; H01L 25/075; H10H 29/80; H10H 29/85; H10H 29/852

(52) U.S. Cl. CPC H10H 29/24; H10H 29/8321; H10H 29/857; H10W 90/00; H10H 29/852

(57) ABSTRACT

A chip package structure includes a circuit substrate, a plurality of light emitting chips, and a package body. The plurality of light emitting chips are arranged on the circuit substrate and divided into four first light emitting chips, four second light emitting chips, and four third light emitting chips. The package body covers the plurality of light emitting chips on the circuit substrate. Any two of the first light emitting chips are not adjacent to each other, any two of the second light emitting chips are not adjacent to each other, and any two of the third light emitting chips are not adjacent to each other. The first light emitting chip, the second light emitting chip, and the third light emitting chip collectively form a pixel, and nine pixels are provided on the circuit substrate.

### FIELD OF THE DISCLOSURE

The present disclosure relates to a chip package structure, and more particularly to a light emitting chip package structure with a fine pitch, which is suitable for use in the display field.

### BACKGROUND OF THE DISCLOSURE

Current chip packaging technology often has production speed and cost issues. To solve these problems, existing technologies use pixel multiplexing to reduce the number of chips used, thereby lowering manufacturing costs and improving manufacturing efficiency. In addition, with the popularity of portable electronic devices, along with the development toward thinner and lightweight features and high resolution, packaging technology is also continuously enhancing the spacing between chips.

Therefore, how to improve the luminous effect of the light emitting chip package structure and lower the manufacturing cost through structural design improvements to overcome the abovementioned defects has become one of the important issues to be addressed in the related field.

### SUMMARY OF THE DISCLOSURE

In response to the above-referenced technical inadequacies, the present disclosure provides a chip package structure.

In order to solve the above-mentioned problems, one of the technical aspects adopted by the present disclosure is to provide a chip package structure, which includes a circuit substrate, a plurality of light emitting chips, and a package body. The plurality of light emitting chips are arranged on the circuit substrate and divided into four first light emitting chips, four second light emitting chips, and four third light emitting chips. The first light emitting chip, the second light-emitting chip, and the third light emitting chip emit light in different colors. The package body covers the plurality of light emitting chips on the circuit substrate. Any two of the first light emitting chips are not adjacent to each other, any two of the second light emitting chips are not adjacent to each other, and any two of the third light emitting chips are not adjacent to each other. The first light emitting chip, the second light emitting chip, and the third light emitting chip collectively form a pixel, and nine pixels are provided on the circuit substrate.

In one of the possible or preferred embodiments, four light emitting areas are defined on a surface of the circuit substrate, the light emitting areas are arranged in a 2×2 array, and each light emitting area includes the first light emitting chip, the second light emitting chip, the third light emitting chip, and an electrical conductor.

In one of the possible or preferred embodiments, the chip package structure further includes a plurality of first electrodes, the circuit substrate is provided with a plurality of holes, positions of the plurality of holes correspondingly correspond to the plurality of light emitting chips and the electrical conductors, the plurality of first electrodes are respectively disposed in the plurality of holes, and each of the plurality of first electrode is electrically connected to a corresponding one of the light emitting chips or a corresponding one of the electrical conductors.

In one of the possible or preferred embodiments, each light emitting chip is fixed on a corresponding one of the first electrodes through an electrically conductive material.

In one of the possible or preferred embodiments, the chip package structure further includes a plurality of electrically conductive connectors each correspondingly connected to the first light emitting chip, the second light emitting chip, the third light emitting chip, and the electrical conductor in close proximity thereto, and each of the plurality of electrically conductive connectors is connected to the light emitting chip through a second electrode.

In one of the possible or preferred embodiments, the electrical conductor is a metal pillar.

In one of the possible or preferred embodiments, each of the plurality of light emitting chips is a vertical light emitting diode chip.

One of the beneficial effects of the present disclosure is that in the chip package structure provided by the present disclosure, by virtue of “the pluarality of light emitting chips being divided into the at least four first light emitting chips, the at least four second light emitting chips, and the at least four third light emitting chips, wherein the first light emitting chip, the second light emitting chip, and the third light emitting chip emit light in different colors,” “any two of the first light emitting chips being not adjacent to each other, any two of the second light emitting chips being not adjacent to each other, and any two of the third light emitting chips being not adjacent to each other,” and “the first light emitting chip, the second light emitting chip, and the third light emitting chip collectively forming the pixel, and at least nine pixels being provided on the circuit substrate,” combined with a software algorithm to realize pixel multiplexing, thereby reducing a number of actual pixels. In other words, the chip package structure of the present disclose, combined with the software algorithm, can achieve an effect of virtualized pixels, effectively reducing a number of chips used and lowering manufacturing costs.

The chip package structure of the present disclosure can be applied to display products with high pixels per inch (PPI) and high light efficiency, such as display panels, but the present disclosure is not limited thereto.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a top view of a chip package structure according to one embodiment of the present disclosure, in which an electrically conductive connector is omitted;

FIG. 2 is a top view of the embodiment shown in FIG. 1, in which the electrically conductive connector is included;

FIG. 3 is a schematic cross-sectional view taken along line III-III of FIG. 2; and

FIG. 4 is a schematic cross-sectional view taken along line IV-IV of FIG. 2.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

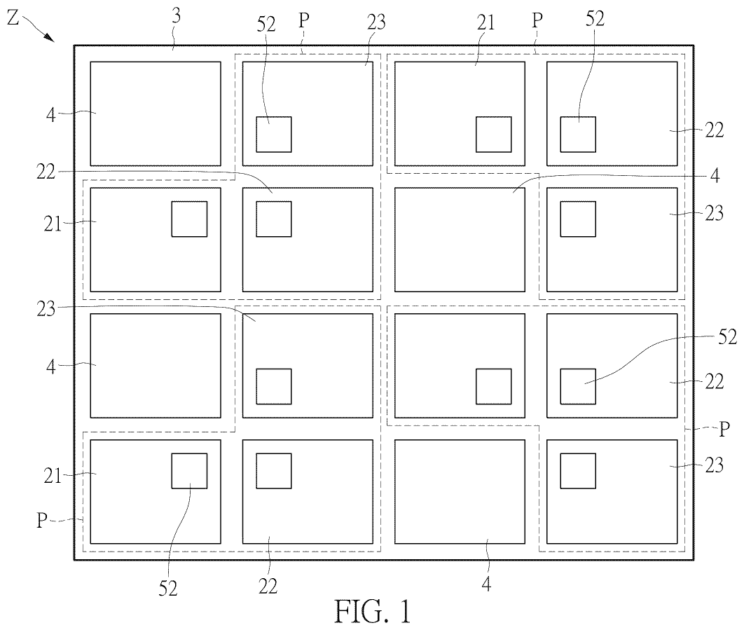

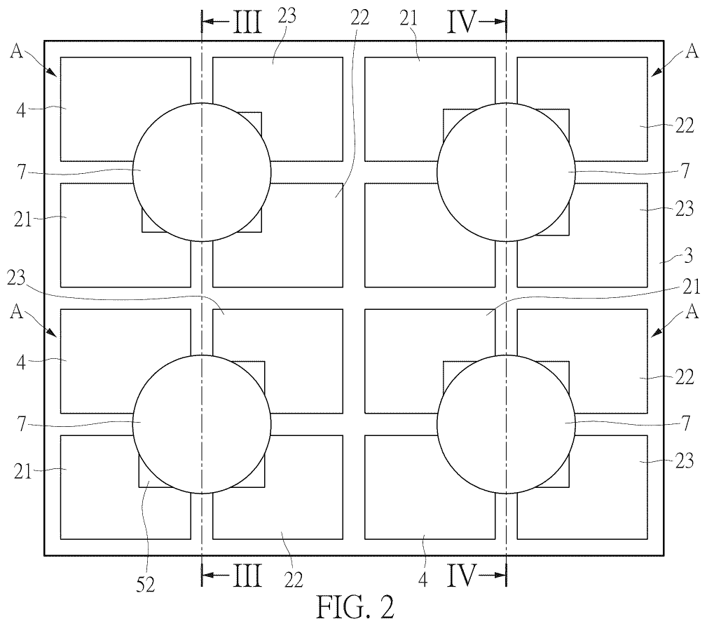

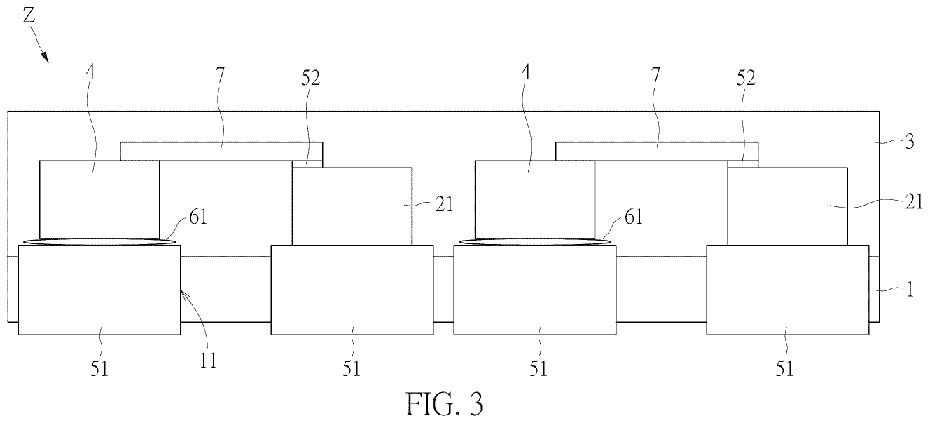

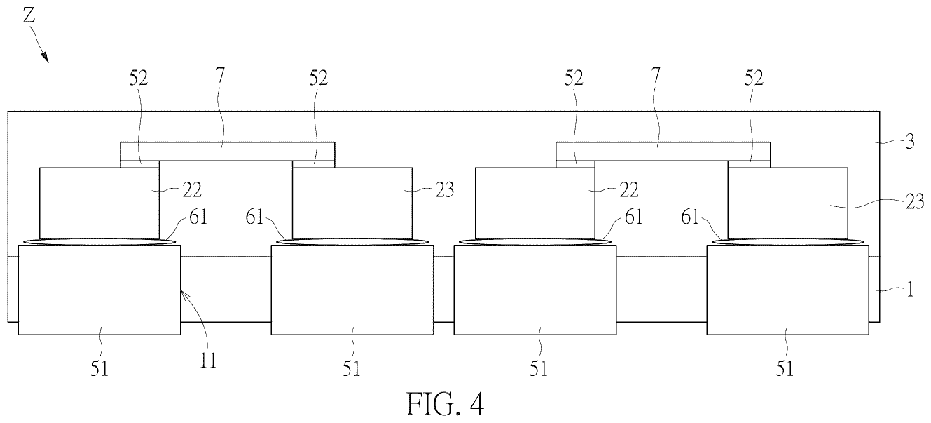

Referring to FIG. 1 to FIG. 4, FIG. 1 is a top view of a chip package structure Z according to one embodiment of the present disclosure, in which an electrically conductive connector 7 is omitted; FIG. 2 is a top view of the embodiment shown in FIG. 1, in which the electrically conductive connector 7 is included; FIG. 3 is a schematic cross-sectional view taken along line III-III of FIG. 2; and FIG. 4 is a schematic cross-sectional view taken along line IV-IV of FIG. 2.

The chip package structure Z includes a circuit substrate 1, a plurality of light emitting chips 2, and a package body 3. The plurality of light emitting chips are arranged on the circuit substrate 1. The circuit substrate 1 is, for example, a bismaleimide triazine resin (BT) substrate, or a substrate made of epoxy molding compound (EMC). In the embodiment shown in FIG. 1, the plurality of light emitting chips 2 are divided into four first light emitting chips 21, four second light emitting chips 22, and the four third light emitting chips 23. The first light emitting chip 21, the second light emitting chip 22, and the third light emitting chip 23 correspondingly emit light in different colors. For example, the first light emitting chip 21 emits light in red, the second light emitting chip 22 emits light in green, and the third light emitting chip 23 emits light in blue. According to some embodiments, the abovementioned light emitting chips are vertical light emitting diode chips. The package body 3 covers the plurality of light emitting chips 2 on the circuit substrate 1. Among the first light emitting chips 21, any two of the first light emitting chips 21 are not adjacent to each other. Among the second light emitting chips 22, any two of the second light emitting chips 22 are not adjacent to each other. Among the third light emitting chips 23, any two of the third light emitting chips 23 are not adjacent to each other. The first light emitting chip 21, the second light emitting chip 22, and the third light emitting chip 23 collectively form a pixel P. In the embodiment shown in FIG. 1, nine pixels P are provided on the circuit substrate 1 (only four combinations of pixels are illustrated in FIG. 1).

As shown in FIG. 1 or FIG. 2, four light emitting areas A are defined on a surface of the circuit substrate 1, and the four light emitting areas A are arranged in a 2×2 array. Each light emitting area A includes the first light emitting chip 21, the second light emitting chip 22, the third light emitting chip 23, and an electrical conductor 4. According to some embodiments, the electrical conductor 4 is a metal pillar, such as a copper pillar, but the present disclosure is not limited thereto.

As shown in FIG. 3 and FIG. 4, the chip package structure Z further includes a plurality of first electrodes 51. The circuit substrate 1 is provided with a plurality of holes 11, and positions of the plurality of holes 11 correspondingly correspond to the plurality of light emitting chips 2 and the electrical conductors 4. The plurality of first electrodes 51 are respectively disposed in the plurality of holes 11, and each first electrode 51 is electrically connected to a corresponding one of the light emitting chips 2 or a corresponding one of the electrical conductors 4. The first electrode 51 is, for example, a pad made of metal. In the embodiment shown in FIG. 3, adjacent first electrodes 51 have different polarities. In the embodiment shown in FIG. 4, adjacent first electrodes 51 have the same polarity. According to some embodiments, the light emitting chips 2 are correspondingly fixed on the first electrodes 51 through an electrically conductive material 61. The electrically conductive material 61 is, for example, a conductive adhesive or a solder ball.

As shown in FIG. 2 to FIG. 4, the chip package structure Z further includes a plurality of electrically conductive connectors 7. The electrically conductive connector 7 is correspondingly connected to the first light emitting chip 21, the second light emitting chip 22, the third light emitting chip 23, and the electrical conductor 4 in close proximity thereto, and the electrically conductive conductor 7 is electrically connected to the light emitting chip 2 through a second electrode 52. Through the electrically conductive connector 7, the first light emitting chip 21, the second light emitting chip 22, and the third light emitting chip 23 are connected to function as a common electrode. The second electrode 52 can be a pad made of metal.

### Beneficial Effects of the Embodiments

One of the beneficial effects of the present disclosure is that in the chip package structure provided by the present disclosure, by virtue of “the pluarality of light emitting chips being divided into the at least four first light emitting chips, the at least four second light emitting chips, and the at least four third light emitting chips, wherein the first light emitting chip, the second light emitting chip, and the third light emitting chip emit light in different colors,” “any two of the first light emitting chips being not adjacent to each other, any two of the second light emitting chips being not adjacent to each other, and any two of the third light emitting chips being not adjacent to each other,” and “the first light emitting chip, the second light emitting chip, and the third light emitting chip collectively forming the pixel, and at least nine pixels being provided on the circuit substrate,” combined with a software algorithm to realize pixel multiplexing, thereby reducing a number of actual pixels. In other words, the chip package structure of the present disclose, combined with the software algorithm, can achieve an effect of virtualized pixels, effectively reducing a number of chips used and lowering manufacturing costs.

The chip package structure of the present disclosure can be applied to display products with high pixels per inch (PPI) and high light efficiency, such as display panels, but the present disclosure is not limited thereto.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip package structure, comprising:
a circuit substrate;
a plurality of light emitting chips arranged on the circuit substrate and divided into at least four first light emitting chips, at least four second light emitting chips, and at least four third light emitting chips, wherein the first light emitting chip, the second light emitting chip, and the third light emitting chip emit light in different colors; and
a package body covering the plurality of light emitting chips on the circuit substrate;
wherein any two of the first light emitting chips are not adjacent to each other, any two of the second light emitting chips are not adjacent to each other, and any two of the third light emitting chips are not adjacent to each other; and
wherein the first light emitting chip, the second light emitting chip, and the third light emitting chip collectively form a pixel, and at least nine pixels are provided on the circuit substrate.

2. The chip package structure according to claim 1, wherein four light emitting areas are defined on a surface of the circuit substrate, the light emitting areas are arranged in a 2×2 array, and each light emitting area includes the first light emitting chip, the second light emitting chip, the third light emitting chip, and an electrical conductor.

3. The chip package structure according to claim 2, further comprising a plurality of first electrodes, wherein the circuit substrate is provided with a plurality of holes, positions of the plurality of holes correspondingly correspond to the plurality of light emitting chips and the electrical conductors, the plurality of first electrodes are respectively disposed in the plurality of holes, and each of the plurality of first electrode is electrically connected to a corresponding one of the light emitting chips or a corresponding one of the electrical conductors.

4. The chip package structure according to claim 3, wherein each light emitting chip is fixed on a corresponding one of the first electrodes through an electrically conductive material.

5. The chip package structure according to claim 3, further comprising a plurality of electrically conductive connectors each correspondingly connected to the first light emitting chip, the second light emitting chip, the third light emitting chip, and the electrical conductor in close proximity thereto, wherein each of the plurality of electrically conductive connectors is connected to the light emitting chip through a second electrode.

6. The chip package structure according to claim 3, wherein the electrical conductor is a metal pillar.

7. The chip package structure according to claim 1, wherein each of the plurality of light emitting chips is a vertical light emitting diode chip.
